(19) United States
(12) Patent Application Publication
(10) Pub. No.: US 2009/0226648 A1
(43) Pub. Date: Sep. 10, 2009

(54) Unknown

(76) Inventors: Michael Wild, Deggendorf (DE); Robert Hartel, Rinchnach (DE); Andreas Buske, Deggendorf (DE); Josef Molz, Zwiesel (DE)

Correspondence Address: RENNER OTTO BOISSELLE & SKLAR, LLP, 1621 EUCLID AVENUE, NINETEENTH FLOOR, CLEVELAND, OH, 44115, US

(21) Appl. No.: 11/872,125

(22) Filed: Oct. 15, 2007

(30) Foreign Application Priority Data
Oct. 17, 2006 (DE) 102006048 997.745

(51) Int. Cl. C03C 17/32; C03C 17/34; B05D 5/08; B05D 3/00; C23C 14/08; C23C 14/02

(52) U.S. Cl. 428/34.7; 428/141; 427/299; 427/230; 427/255.14; 427/585; 427/447; 65/17.2; 204/192.15; 427/309

(57) ABSTRACT

The present invention relates to a household glass product, comprising a glass surface and a switchable hydrophobic or hydrophilic coating which is applied to at least a region of the glass surface, wherein at least the region of the surface of the household glass product to which the coating is applied is roughened and has a root mean square roughness value Ra in the range of 0.1 to 50 nm, so that the surface has a super-hydrophobic or super-hydrophilic property, and to a method for producing such a household glass product.

The present invention relates to a household glass product, comprising a glass surface and a switchable hydrophobic or hydrophilic polymer coating which is applied to at least a region of the glass surface, wherein at least the region of the surface of the household glass product to which the coating is applied is roughened and has a root mean square roughness value Ra in the range of 0.1 to 50 nm, so that the surface is provided with a super-hydrophobic or super-hydrophilic property, and to a method for producing such a household glass product.

Household glass products within the scope of the present invention shall be understood as hollow glasses, particularly beverage glasses, as well as glazed and enameled household articles.

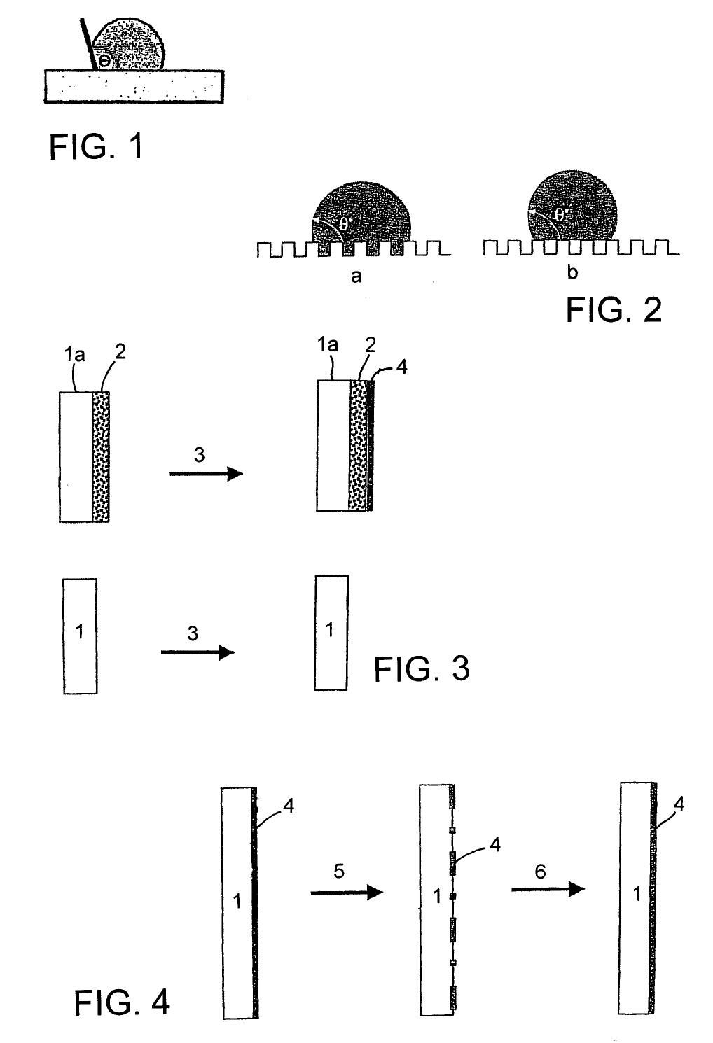

Within the scope of the present invention, the hydrophobicity or hydrophilicity of a surface is also referred to as the wettability thereof. This wettability can be represented quantitatively by the static contact angle (hereinafter referred to as contact angle for reasons of simplicity). The contact angle denotes the angle θ shown in FIG. 1 between the surface and a water drop applied to this surface. In the scope of the present invention, surfaces that form a contact angle larger than 90° with water are referred to as hydrophobic, and surfaces that form a contact angle less than 90° with water are referred to as hydrophilic. The contact angle depends on the surface material on the one hand, and on the surface texture on the other hand. Methods for determining the contact angle are generally based on optical methods and are known from the state of the art.

Alternatively, the wettability of a surface can be represented by the roll-off angle. The roll-off angle shall be understood as the angle of inclination of a basically planar, yet structured surface in relation to the horizontal line, wherein a vertical water drop having the volume 10 μl is moved by gravity if the surface is inclined by the roll-off angle. A hydrophobic surface in general exists if the roll-off angle is less than 20°.

Water is generally used in conjunction with alkaline cleaning agents to clean products that are to be cleaned in dishwashers, for example glasses and tableware. It is advantageous that the surface to be cleaned be hydrophilic. Improved wettability by water is achieved with a hydrophilic surface, resulting in an excellent cleaning effect.

However, following the cleaning step with water, the hydrophilicity of the surface delays the drying process because the water present on the surface drips or runs off with insufficient speed. So as to expedite the drying of the cleaned glasses or the cleaned tableware, in general rinse aids are used which, unlike the cleaning agent, are adjusted to be acidic (for example by means of citric acid). Rinse aids comprise tensides, which are surface-active compounds and reduce the surface tension of the water, thus facilitating the draining of the water from the cleaned surface.

The use of rinse aids, however, has the disadvantage that an excess thereof results in clearly visible streaking of the glasses and tableware and leaves behind a thin tenside film on the products to be cleaned. If, however, no rinse aid is used, the drying process of the products to be cleaned is delayed and limescale forms on the surface. In either case, labor-intensive subsequent drying or polishing, which may result in breakage, is required, which is particularly disadvantageous in the food service industry.

It is therefore the object of the invention to provide a household glass product, for example a product to be cleaned such as a beverage glass or tableware, which is hydrophilic during the washing process and therefore enables good cleaning of the surface, but which, after the washing process, is hydrophobic and therefore enables quick drying without the formation of limescale on the surface and without requiring the use of a rinse aid comprising surfactants. Furthermore, the household glass product should be oleophobic when used, which is to say grease and dirt-repellent. It is furthermore an object of the present invention to provide a method for producing such a household glass product.

These objects are achieved by the embodiments characterized in the claims.

In particular, a household glass product is provided, which comprises a glass surface and a switchable hydrophobic or hydrophilic polymer coating that is applied at least to a region of the glass surface, wherein at least the region of the surface of the household glass product to which the coating is applied is roughened and has a root mean square roughness value Ra in the range of 0.1 to 50 nm, so that the surface is provided with a super-hydrophobic or super-hydrophilic property.

The household glass product can be any suitable glass product or glazed or enameled product, which must be cleaned on a regular basis. It is particularly preferred if the household glass product is a product to be washed such as hollow glass, particularly beverage glasses, or glazed or enameled tableware, such as plates, cups, and pots. The surface of such a household glass product may therefore be a glass surface, a glazed surface or an enameled surface, which hereinafter is simply referred to as a glass surface.

The switchable hydrophobic or hydrophilic polymer coating is applied to at least a region of the glass surface of the household glass product. Preferably, the coating is applied to the entire surface of the household glass product. The coating, however, may be completely or partially removed, for example as a result of use or cleaning of the household glass product, and is therefore not permanent. The switchable hydrophobic or hydrophilic coating applied to the glass surface of the household glass product preferably has a thickness ranging between 0.1 and 50 nm.

Within the scope of the present invention, the hydrophobic or hydrophilic polymer coating shall be understood as a polymer coating which can change reversibly from a hydrophobic state into a hydrophilic state. The surface is therefore “switchable” and may be reversibly changed from one state to the other as a result of the influence of an external parameter. This external parameter may be of physical nature (for example a temperature change or the incidence of light) or of chemical nature (for example a reversible chemical reaction or a change in the pH value). Preferably, the polymer coating is either hydrophobic or hydrophilic as a function of the pH value or as a function of the temperature. The change from a hydrophobic state to a hydrophilic state, and vice versa, may occur, for example, by a change of conformation or by a chemical reaction of a compound present in the coating.

The applied switchable hydrophobic or hydrophilic polymer coating comprises at least one compound which is suited to reversibly switch the coating from a hydrophobic state to a hydrophilic state as a result of the influence of an external parameter. Such compounds are known from the state of the art (key word “smart polymers”). Preferably, the switchable hydrophobic or hydrophilic coating comprises a compound which is selected from the group consisting of poly(N-isopropylacrylamide) (PNIPAAM) and poly(N,N-diethylacrylamide), or a copolymer comprising poly(N-isopropylacrylamide) and/or poly(N,N-diethylacrylamide), which are known as switchable polymers or smart polymers from the state of the art. Furthermore, PEO-PPO-PEO triblock copolymers, PEG-PLA-PEG triblock copolymers or PS-PAA block copolymers may also be used (PEO=polyethylene oxide, PPO=polypropylene oxide, PEG=polyethylene glycol, PLA=polylactic acid, PS=polystyrene, PAA=polyacrylic acid).

Preferably, at a pH value of less than approximately 7.0, the polymer coating is hydrophobic and at a pH value of greater than approximately 7.0 it is hydrophilic. The coating, however, can also change from a hydrophobic state into a hydrophilic state at another suitable pH value, which preferably ranges between 3.0 and 10.0.

As a result of this switchability of the applied polymer coating, it is possible according to the present invention to produce household glass products which have hydrophilic properties, for example during a washing process in an alkaline medium, and therefore enable thorough cleaning of the surfaces. In a subsequent drying step, in the presence of an acidic medium, such as citric acid, the household glass products then exhibit hydrophobic properties, enabling the water to drip off quickly and thus preventing the formation of limescale. This hydrophobic property is preferably combined with an oleophobic property and is maintained even after the drying process, which is to say, during use. In this way, the glass surface of the household glass product is also provided with grease and dirt-repellent properties during use.

Preferably, the coating is hydrophobic at a temperature greater than approximately 32° C. and is hydrophilic at a temperature of less than approximately 32° C. The coating, however, can also change from a hydrophobic state to a hydrophilic state at another suitable temperature, which preferably ranges between 20° C. and 100° C.

As a result of this temperature-dependent switchability of the applied coating, it is possible according to the present invention to produce a household glass product which has hydrophilic properties, for example during the washing process at a temperature of less than 32° C., and therefore enables thorough cleaning of the surface. In the subsequent drying step at a temperature above 32° C., the household glass product then exhibits hydrophobic properties, enabling the water to drip off quickly and thus preventing the formation of limescale.

Preferably, the coated household glass product loses the hydrophobic property over the course of approximately one second to approximately one day, preferably over the course of approximately one minute to approximately 10 minutes. This is particularly advantageous if the coated household glass product is a hollow glass, particularly a beverage glass. In this way, it is possible that the beverage glass, after washing, is no longer hydrophobic on the inside thereof and therefore has sufficient wettability by a beverage.

At least the region of the surface of the coated household glass product to which the coating is applied is roughened and has a root mean square roughness value Ra in the range of 0.1 to 50 nm, so that the surface is provided with super-hydrophobic or super-hydrophilic properties.

In the scope of the present application, the term “super-hydrophobicity” shall be understood as the hydrophobic property of a surface which, in relation to water, has a contact angle θ of at least 150°. Super-hydrophobicity is frequently also referred to as the “lotus effect”. Super-hydrophobicity of a surface results in particularly easy dripping or rolling off of water from the surface, which supports fast drying of the surface and hampers the adhesion of grease and dirt to the surface. Similarly, in the scope of the present invention, the term “super-hydrophilicity” shall be understood as the property of a hydrophilic surface which, in relation to water, has a contact angle θ of no more than 30°.

It is known that the contact angle (and thus wettability) for any given surface material depends on the surface roughness. In this context, two states are known, namely (a) the Wenzel state and (b) the Cassie-Baxter state. In the Wenzel state, the drop of fluid completely covers the surface (see FIG. 2a). This state can be substantially represented by the following equation:

cosθ*=r·cosθ Equation (1)

wherein θ* is the apparent contact angle of the drop in relation to the rough surface, θ is the contact angle of a smooth surface of the same material, and r is the ratio between the actual surface and the projected surface and therefore a surface roughness measure. From equation (1) it can be deduced that the contact angle on a hydrophobic surface (θ>90°) increases as the roughness r increases (θ*>θ), which is to say, as roughness increases, the hydrophobicity of a hydrophobic surface rises. Vice versa, the contact angle of a hydrophilic surface decreases with increasing roughness (θ*<θ). In this way, a hydrophobic surface can be turned into a super-hydrophobic surface, and a hydrophilic surface can be turned into a super-hydrophilic surface by increasing the surface roughness.

The Cassie-Baxter state furthermore considers that air bubbles are trapped between the drop and the rough surface (see FIG. 2b). This case can be substantially represented by the following equation:

cosθ*=φₛ·(cos θ+1)−1 Equation (2)

wherein θ and θ* are as defined above and φₛ is the portion of the surface in contact with the fluid.

According to the present invention, the surface of the coated household glass product is roughened such that in conjunction with the hydrophobic or hydrophilic surface coating, a super-hydrophobic or super-hydrophilic surface is produced. For this purpose, the surface of the coated household glass product has a root mean square roughness value Ra in the range of 0.1 to 50 nm, preferably between 5 and 30 nm.

In a preferred embodiment, the coated household glass product according to the invention comprises an auxiliary layer that is applied to at least a region of the glass surface, the layer having a root mean square roughness value Ra ranging between 0.1 and 50 nm, with an isoelectric point at a higher pH value than that of the household glass product or the glass surface thereof, and wherein the switchable hydrophobic or hydrophilic coating is applied to at least a region of the surface of the auxiliary layer. The above roughness can be achieved by producing a layer in a controlled process or by subsequent roughening.

An isoelectric point of a surface is the pH value at which the net charge on the surface equals zero. According to the present invention, it is advantageous to specifically select an auxiliary layer whose isoelectric point differs from the isoelectric point of the corresponding substrate, which is to say the household glass product or the glass surface thereof, and from the isoelectric points of further surfaces with which the switchable hydrophobic or hydrophilic coating may come in contact during the application step. Preferably, the auxiliary layer has an isoelectric point with a higher pH value than the isoelectric point of the substrate, which is to say of the household glass product or the glass surface thereof.

The auxiliary layer can be made of any suitable material. Preferably the auxiliary layer is made of a material selected from the group consisting of silicon oxide, silicon carbide and silicon nitride, metal oxides, metal carbides, metal nitrides, metal oxycarbides and metal oxynitrides, mixed silicon and/or metal carbides, nitrides, oxides, oxycarbides and oxynitrides, in stoichiometric or non-stoichiometric compositions, and diamond and diamond-like carbon. Particularly preferably, the auxiliary layer is made of silicon oxide, aluminum oxide and/or titanium oxide, with aluminum oxide being more preferred.

The auxiliary layer has a thickness of 1 nm to 100 μm; preferably, the thickness of the auxiliary layer is between 20 nm and 40 μm, with 50 nm to 1 μm being particularly preferred.

As a result of the auxiliary layer, which is applied to at least a region of the surface of the household glass product, it is possible, due to the differences in the isoelectric points, to apply the switchable hydrophobic or hydrophilic polymer coating selectively only to a desired region of the household glass product, namely to the region of the glass surface that is provided with the auxiliary layer. A glass substrate surface with a given pH value, for example, has an opposite-sign surface charge to an aluminum oxide auxiliary layer. By suitably selecting the hydrophobic or hydrophilic polymer coating, the switchable hydrophobic or hydrophilic coating can be deposited substantially only on the auxiliary layer, but not on the region of the glass surface that is provided with the auxiliary layer.

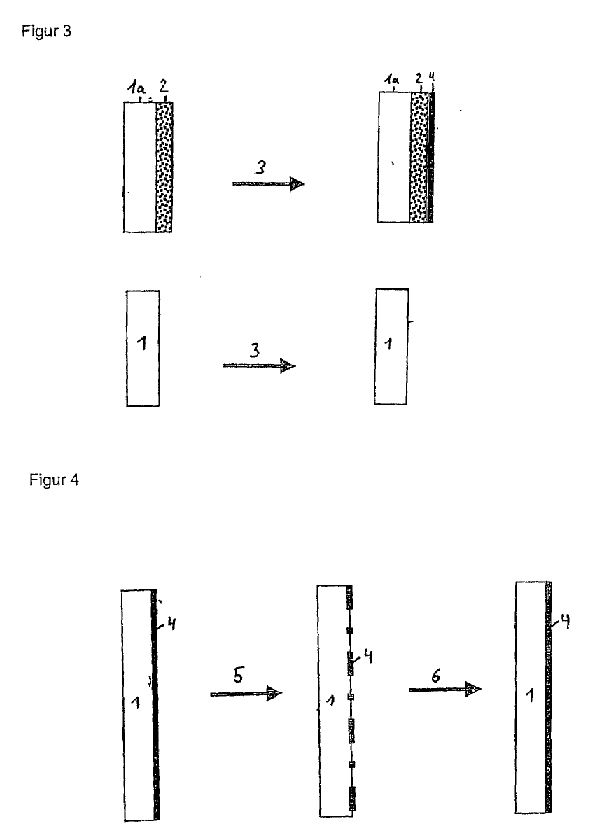

According to the present invention, it is possible in this way to selectively provide only the desired regions of the glass surface with the hydrophobic or hydrophilic coating, which is illustrated in FIG. 3.

FIG. 3 shows two substrates 1 and 1a, wherein substrate 1a is coated with a suitable auxiliary layer 2. If, in coating step 3, both substrates are exposed to the components of the hydrophobic or hydrophilic coating or the precursor thereof, the coating 4 is deposited substantially only on the substrate provided with the auxiliary layer.

Furthermore, by applying the auxiliary layer to at least a region of the glass surface, the scratch resistance or hardness of the surface can be significantly increased. For example, silicate glass comprising an aluminum oxide auxiliary layer measuring 50 to 500 nm in thickness has a higher surface hardness and scratch resistance than non-coated silicate glass.

The auxiliary layer, however, is not limited to materials having an isoelectric point at a higher pH value than that of the substrate. The selectivity achieved by the auxiliary layer can also be achieved, for example, using a flotation method (froth flotation) for separating mineral mixtures. This method takes advantage of the fact that certain surface-active substances (collectors) selectively adsorb on certain mineral surfaces and hydrophobize them. By injecting air, the hydrophobized minerals are removed with the froth from the suspension. Hydrophilic minerals remain, thus achieving a separation effect.

The present invention furthermore relates to a method for producing a household glass product, comprising (a) providing a glass surface of a household glass product, (b) roughening of at least a region of this surface so that the roughened surface has a root mean square roughness value Ra in the range of 0.1 to 50 nm, and (c) applying a hydrophobic or hydrophilic polymer coating to the roughened region of the surface, so that the surface is provided with super-hydrophobic or super-hydrophilic properties.

The switchable hydrophobic or hydrophilic polymer coating is applied to at least a region of the surface of the corresponding household glass product. Preferably, the coating is applied to the entire surface of the household glass product. The hydrophobic or hydrophilic coating can be applied by means of conventional methods known from the prior art. For example, the application can be performed by spraying, immersing, flooding, condensation from the gaseous phase or spreading. In a preferred embodiment, the coating is applied during a cleaning process in a dishwasher.

The switchable hydrophobic or hydrophilic polymer coating applied to the household glass product comprises at least one compound which is suited to reversibly switch the coating from a hydrophobic state into a hydrophilic state as a result of the influence of an external parameter. Such compounds are known from the state of the art. Preferably, the switchable hydrophobic or hydrophilic coating is a compound which is selected from the group consisting of poly(N-isopropylacrylamide) and poly(N,N-diethylacrylamide), or a copolymer comprising poly(N-isopropylacrylamide) and/or poly(N,N-diethylacrylamide), which are known as switchable polymers or smart polymers from the state of the art.

The thickness of the hydrophobic or hydrophilic coating preferably ranges between 0.1 to 50 nm, with a range of 5 to 30 nm being more preferred. As a result of this low thickness, it is possible to completely or partially remove the coating over time through use or repeated cleaning of the coated household glass product. It is therefore advantageous to regenerate the coating on a regular basis. According to the present invention, this preferably occurs during cleaning in a dishwasher, in that either the dishwashing detergent, the rinse aid or a product replacing the rinse aid comprises an active component or a precursor of the hydrophobic or hydrophilic coating which is reapplied to the household glass product during the regeneration process. In this way, it is advantageously possible to permanently maintain or renew the hydrophobic or hydrophilic property of the household glass product. It is also possible that the switchable hydrophobic or hydrophilic coating is first substantially completely removed during the cleaning step in the dishwasher and is then regenerated in the subsequent treatment step using the rinse aid or the product replacing the rinse aid, which comprises the appropriate coating component or precursor thereof (see FIG. 4).

FIG. 4 shows a substrate 1 comprising a switchable hydrophobic or hydrophilic coating 4, which is completely or partially removed by use, aging or cleaning 5. During a regeneration step 6, the components of the coating or the precursor thereof from the liquid or gaseous phase are added again, thus restoring the coating 4. As a result, the end state after regeneration substantially corresponds to the original state.

In a preferred embodiment, the method according to the invention comprises the step (d) of applying an auxiliary layer to at least a region of the surface of the household glass product prior to the step (b) of roughening the surface, wherein the auxiliary layer has an isoelectric point with a higher pH value than that of the substrate, which is to say, of the household glass product or the glass surface thereof.

As a result of the auxiliary layer, which is applied to at least a region of the surface of the household glass product, due to the differences in the isoelectric points, the convetible hydrophobic or hydrophilic coating can be applied selectively only to a desired region of the household glass product, namely to the region of the glass surface that is provided with the auxiliary layer. This applies to the initial application of the hydrophobic or hydrophilic coating as well as to the regenerative application of the coating at a later time.

The auxiliary layer can be made of any suitable material. Preferably, the auxiliary layer is made of a material selected from the group consisting of silicon oxide, silicon carbide and silicon nitride, metal oxides, metal carbides, metal nitrides, metal oxycarbides and metal oxynitrides, mixed silicon and/or metal carbides, nitrides, oxides, oxycarbides and oxynitrides, in stoichiometric or non-stoichiometric compositions, and diamond and diamond-like carbon. Particularly preferably, the auxiliary layer is made of silicon oxide, aluminum oxide and/or titanium oxide, with aluminum oxide being more preferred.

The auxiliary layer has a thickness of 1 nm to 100 μm; preferably, the thickness of the auxiliary layer is between 20 nm and 40 μm, with 50 nm to 1 μm being particularly preferred.

The auxiliary layer can be applied by suitable methods known from the prior art. Preferably, the auxiliary layer is applied by means of physical or chemical vapor deposition, a sol-gel method, sputtering, powder flame spray coating, in the form of a suspension or in the form of a liquid or gaseous precursor. The application of the auxiliary layer by means of sputtering, particularly magnetron sputtering, is particularly preferred.

The surface of the coated household glass product can be roughened such that either the glass surface itself is roughened, or such that the auxiliary layer applied to the substrate is roughened. For this purpose, any surface roughening methods known from the prior art can be employed. Preferably, roughening is performed by an etching or leaching method. In a further preferred embodiment of the method according to the invention, the roughness is produced by applying the auxiliary layer using a sol-gel method, wherein a suitable nano-powder is added to the sol, resulting in a rough surface for the applied auxiliary layer.

According to the inventive method, the surface of the coated household glass product is roughened such that, in conjunction with the hydrophobic or hydrophilic surface coating material, a super-hydrophobic or super-hydrophilic surface is produced. For this purpose, the surface of the coated substrate has a root mean square roughness value Ra in the range of 0.1 to 50 nm, preferably between 5 and 30 nm.

According to the present invention, in this way a household glass product is provided, having surface that, during cleaning, has super-hydrophilic properties and can therefore be cleaned easily and effectively, and after cleaning has super-hydrophobic and at the same time oleophobic properties. The household glass product dries quickly after cleaning, without requiring the use of rinse aids comprising surfactants. Furthermore, it is grease and dirt-repellent during use. In addition, it is possible according to the present invention to selectively bring about these properties only in a region of the surface, by applying a suitable auxiliary layer to the household glass product, the auxiliary layer also lending hardness and scratch resistance to the household glass product.

In this way, for example, particularly scratch-resistant glass surfaces can be obtained, which do not become dirty as quickly, are easier to clean and dry quickly and with few stains.

FIG. 1 shows a schematic illustration of a water drop applied to a surface with a contact angle θ between the drop and the surface.

FIG. 2 shows a schematic illustration of a drop applied to a rough surface. In this figure, (a) represents the Wenzel state and (b) the Cassie-Baxter state.

FIG. 3 shows the selective application of the hydrophobic or hydrophilic coating onto the substrate that is provided with an auxiliary layer, the substrate being the household glass product or the glass surface thereof.

FIG. 4 shows the regeneration of the hydrophobic or hydrophilic coating.

1. A household glass product, comprising a glass surface and a switchable hydrophobic or hydrophilic polymer coating that is applied to at least a region of the glass surface, wherein at least the region of the surface of the household glass product to which this coating is applied is roughened and has a root mean square roughness value Ra in the range of 0.1 to 50 nm, so that the surface is provided with a super-hydrophobic or super-hydrophilic property.

2. The household glass product according to claim 1, wherein the household glass product is a hollow glass, particularly a beverage glass, or glazed or enameled tableware.

3. The household glass product according to claim 1, wherein the coating is either hydrophobic or hydrophilic as a function of the pH value or as a function of the temperature.

4. A household glass product according to claim 1, wherein the switchable hydrophobic or hydrophilic polymer coating comprises a smart polymer selected from the group consisting of poly(N-isopropylacrylamide) and poly(N,N-diethylacrylamide).

5. A household glass product according to claim 1, wherein the root mean square roughness value Ra of the roughened surface ranges between 5 and 30 nm.

6. A household glass product according to claim 1, wherein the household glass product comprises an auxiliary layer which is applied to at least a region of the surface of the glass product, the isoelectric point thereof having a higher pH value than that of the glass product, and wherein the switchable hydrophobic or hydrophilic coating is applied to at least a region of the surface of the auxiliary layer.

7. The household glass product according to claim 6, wherein the auxiliary layer is made of a material selected from the group consisting of silicon oxide, silicon carbide and silicon nitride, metal oxides, metal carbides, metal nitrides, metal oxycarbides and metal oxynitrides, mixed silicon and/or metal carbides, nitrides, oxides, oxycarbides and oxynitrides, in stoichiometric or non-stoichiometric compositions, and diamond and diamond-like carbon.

8. The household glass product according to claim 7, wherein the auxiliary layer is made of silicon oxide, aluminum oxide and/or titanium oxide.

9. The household glass product according to claim 7, wherein the auxiliary layer has a thickness ranging between 20 nm and 40 μm.

10. The household glass product according to claim 9, wherein the auxiliary layer has a thickness ranging between 50 nm and 1 μm.

11. A method for producing a coated household glass product, comprising the following steps:
(a) providing a household glass product having a glass surface,
(b) roughening at least a region of the surface of the household glass product so that the roughened surface has a root mean square roughness value Ra in the range of 0.1 to 50 nm, and
(c) applying a hydrophobic or hydrophilic polymer coating onto the roughened region of the surface of the household glass product,
so that the surface is provided with a super-hydrophobic or super-hydrophilic property.

12. The method according to claim 11, wherein the household glass product is a hollow glass, particularly a beverage glass, or glazed or enameled tableware.

13. The method according to claim 11, wherein the switchable hydrophobic or hydrophilic polymer coating is made of a smart polymer selected from the group consisting of poly(N-isopropylacrylamide) and poly(N,N-diethylacrylamide).

14. A method according to claim 11, further comprising the step (d) of applying an auxiliary layer having a root mean square roughness value Ra in the range of 0.1 to 50 nm to at least a region of the surface of the household glass product prior to the step (b) of roughening the surface, wherein the auxiliary layer has an isoelectric point with a higher pH value than that of the glass product.

15. The method according to claim 14, wherein the auxiliary layer is made of a material selected from the group consisting of silicon oxide, silicon carbide and silicon nitride, metal oxides, metal carbides, metal nitrides, metal oxycarbides and metal oxynitrides, mixed silicon and/or metal carbides, nitrides, oxides, oxycarbides and oxynitrides, in stoichiometric or non-stoichiometric compositions, and diamond and diamond-like carbon.

16. The method according to claim 15, wherein the auxiliary layer is made of silicon oxide, aluminum oxide and/or titanium oxide.

17. A method according to claim 14, wherein the auxiliary layer has a thickness ranging between 20 nm and 40 μm.

18. A method according to claim 14, wherein the auxiliary layer is applied by means of physical or chemical vapor deposition, a sol-gel method, sputtering, powder flame spray coating, in the form of a suspension or in the form of a liquid or gaseous precursor.

19. The method according to claim 18, wherein the auxiliary layer is applied by sputtering, particularly magnetron sputtering.

20. A method according to claim 11, wherein roughening is performed by means of an etching or leaching method.
